(19) United States
(12) Patent Application Publication
(10) Pub. No.: US 2013/0100978 A1
(43) Pub. Date: Apr. 25, 2013

(54) HOLE BLOCKING LAYER FOR THE PREVENTION OF HOLE OVERFLOW AND NON-RADIATIVE RECOMBINATION AT DEFECTS OUTSIDE THE ACTIVE REGION

(71) Applicant: The Regents of the University of California, Oakland, CA (US)

(72) Inventors: Matthew T. Hardy, Goleta, CA (US); Po Shan Hsu, Arcadia, CA (US); Steven P. DenBaars, Goleta, CA (US); James Stephen Speck, Goleta, CA (US); Shuji Nakamura, Santa Barbara, CA (US)

(73) Assignee: THE REGENTS OF THE UNIVERSITY OF CALIFORNIA, Oakland, CA (US)

(21) Appl. No.: 13/659,191

(22) Filed: Oct. 24, 2012

Related U.S. Application Data
(60) Provisional application No. 61/550,870, filed on Oct. 24, 2011.
(60) Provisional application No. 61/550,874, filed on Oct. 24, 2011.

(51) Int. Cl. H01L 29/201; H01S 5/343; H01L 33/04

(52) U.S. Cl. 372/45.012; 257/15; 257/13; 257/E29.168; 257/E33.032

(57) ABSTRACT

An (Al,In,B,Ga)N based device including a plurality of (Al,In,B,Ga)N layers overlying a semi-polar or non-polar GaN substrate, wherein the (Al,In,B,Ga)N layers include at least a defected layer, a blocking layer, and an active region, the blocking layer is between the active region and the defected layer of the device, and the blocking layer has a larger band gap than surrounding layers to prevent carriers from escaping the active region to the defected layer. One or more (AlInGaN) device layers are above and/or below the (Al,In,B,Ga)N layers. Also described is a nonpolar or semipolar (Al,In,B,Ga)N based optoelectronic device including at least an active region, wherein stress relaxation (Misfit Dislocation formation) is at heterointerfaces above and/or below the active region.

### CROSS REFERENCE TO RELATED APPLICATIONS

This application claims the benefit under 35 U.S.C. Section 119(e) of the following co-pending and commonly-assigned applications:

U.S. Provisional Application Ser. No. 61/550,870, filed Oct. 24, 2011, by Matthew T. Hardy, Po Shan Hsu, Steven P. DenBaars, James S. Speck, and Shuji Nakamura, entitled “A HOLE BLOCKING LAYER FOR THE PREVENTION OF HOLE OVERFLOW AND NON-RADIATIVE RECOMBINATION AT DEFECTS OUTSIDE THE ACTIVE REGION,” attorney's docket number 30794.434-US-P1 (2012-239); and

U.S. Provisional Application Ser. No. 61/550,874, filed Oct. 24, 2011, by Po Shan Hsu, Matthew T. Hardy, Steven P. DenBaars, James S. Speck, and Shuji Nakamura, entitled “NONPOLAR/SEMIPOLAR (AL,IN,B,GA)N LASERS WITH STRESS RELAXATION AT THE P-CLADDING/P-WAVEGUIDING AND N-CLADDING/N-WAVEGUIDING HETEROINTERFACES,” attorney's docket number 30794.437-US-P1 (2012-247); which applications are incorporated by reference herein.

This application is related to the following co-pending and commonly-assigned U.S. patent applications:

U.S. Utility application Ser. No. 12/861,652, filed on Aug. 23, 2010, by Hiroaki Ohta, Feng Wu, Anurag Tyagi, Arpan Chakraborty, James S. Speck, Steven P. DenBaars, and Shuji Nakamura, entitled “ANISOTROPIC STRAIN CONTROL IN SEMIPOLAR NITRIDE QUANTUM WELLS BY PARTIALLY OR FULLY RELAXED ALUMINUM INDIUM GALLIUM NITRIDE LAYERS WITH MISFIT DISLOCATIONS,” attorney's docket number 30794.318-US-U1 (2009-743-2), which application claims the benefit under 35 U.S.C. Section 119(e) of U.S. Provisional Application Ser. No. 61/236,059, filed on Aug. 21, 2009 by Hiroaki Ohta, Feng Wu, Anurag Tyagi, Arpan Chakraborty, James S. Speck, Steven P. DenBaars, and Shuji Nakamura, entitled “ANISOTROPIC STRAIN CONTROL IN SEMIPOLAR NITRIDE QUANTUM WELLS BY PARTIALLY OR FULLY RELAXED ALUMINUM INDIUM GALLIUM NITRIDE LAYERS WITH MISFIT DISLOCATIONS,” attorney's docket number 30794.318-US-P1 (2009-743-1); and

U.S. Utility application Ser. No. 12/861,532, filed on Aug. 23, 2010, by Hiroaki Ohta, Feng Wu, Anurag Tyagi, Arpan Chakraborty, James S. Speck, Steven P. DenBaars, and Shuji Nakamura, entitled “SEMIPOLAR NITRIDE-BASED DEVICES ON PARTIALLY OR FULLY RELAXED ALLOYS WITH MISFIT DISLOCATIONS AT THE HETEROINTERFACE,” attorney's docket number 30794.317-US-U1 (2009-742-2), which application claims the benefit under 35 U.S.C. Section 119(e) of U.S. Provisional Application Ser. No. 61/236,058, filed on Aug. 21, 2009, by Hiroaki Ohta, Feng Wu, Anurag Tyagi, Arpan Chakraborty, James S. Speck, Steven P. DenBaars, and Shuji Nakamura, entitled “SEMIPOLAR NITRIDE-BASED DEVICES ON PARTIALLY OR FULLY RELAXED ALLOYS WITH MISFIT DISLOCATIONS AT THE HETEROINTERFACE,” attorney's docket number 30794.317-US-P1 (2009-742-1);

all of which applications are incorporated by reference herein.

### BACKGROUND OF THE INVENTION

1. Field of the Invention

This invention relates to a method of fabricating optoelectronic and electronic devices, and devices fabricated using the method.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

Despite recent progress, the performance of green light emitting diodes (LEDs) and laser diodes (LDs) is much lower than equivalent devices emitting in the blue or violet regimes [1-2]. Active regions operating in the green regime require Indium (In) compositions in the quantum wells (QWs) of around 30%. Due to the large lattice mismatch between InN and GaN, of around 10%, such structures must be grown at very high strain (3% for In_{0.3}Ga_{0.7}N), degrading crystal quality, and leading to large piezoelectric induced electric fields in the quantum wells. Stress relaxation also limits the composition and thickness of InGaN waveguiding layers in LDs [1].

For traditional planar c-plane and nonpolar strained heteroepitaxy, stress relaxation typically does not occur via slip due to the absences of resolved shear stress on the c-plane, which is the most favorable slip system. However, c-plane slip has been observed on (20-21) and (11-22) semipolar orientations, which have significant resolved shear stress on the c-plane [2]. Relaxation on semipolar (20-21) (and (11-22) GaN) occurs initially by slip on the c-plane, allowing stress relaxation parallel to the a-direction (and m-direction), and a small degree of stress relaxation parallel to the projected c-direction due to the Poisson effect. Relaxation occurs through the creation of an array of misfit dislocations via threading dislocation (TD) glide. Subsequently grown layers coherent to this partially relaxed buffer layer can then be grown with a modified in-plane lattice constant, leading to a change in the lattice mismatch induced strain. For example, growing a high composition InGaN layer on a partially relaxed InGaN buffer layer will lead to reduced strain for the high InGaN layer. Anisotropic strain reduction may lead to fewer non-radiative defects during growth and modified polarization and gain properties.

The misfit dislocations (MDs) formed as a result of relaxation are non-radiative recombination centers. Typically they can be buried far away from the active region and have negligible effect on device performance. However, if the MDs are close enough to the active region they can act as a carrier a sink and draw carriers out of the active region, leading to greatly reduced internal quantum efficiency. If the relaxed buffer is also used as the lower waveguiding layer, the relaxed interface can only be moved so far from the active region before confinement factor drops off sharply.

A typical laser structure requires an n-cladding layer, an n-waveguiding layer, a multi quantum well (MQW) active region, an electron blocking layer, a p-waveguiding layer, and p-cladding layer. The structure may also contain a hole blocking layer between the n-waveguiding layer and MQW active region. The waveguiding and cladding layers are (Al,In,B,Ga)N alloys of different composition such that the cladding layers have lower refractive indices than the waveguiding layers. Growth of a highly strained nonpolar and semipolar heterostructure can sometimes lead to the formation of MDs at multiple heterointerfaces. Consequently, current devices are fully coherent (Al,In,B,Ga)N semipolar and nonpolar lasers waveguide structures without stress relaxation at any of the heterointerfaces.

### SUMMARY OF THE INVENTION

To overcome the limitations in the prior art described above, and to overcome other limitations that will become apparent upon reading and understanding the present specification, the present invention discloses an (Al,In,B,Ga)N based device comprising a plurality of (Al,In,B,Ga)N layers overlying a semi-polar or non-polar GaN substrate, wherein the (Al,In,B,Ga)N layers comprise at least a defected layer, a blocking layer, and an active region, the blocking layer is between the active region and the defected layer of the device, and the blocking layer comprises a larger band gap than surrounding layers to prevent carriers from escaping the active region to the defected layer; and one or more (AlInGaN) device layers above and/or below the (Al,In,B,Ga)N layers.

The blocking layer can be a high bandgap layer blocking one or more carriers and the carriers are holes.

The blocking layer can be an AlGaN layer.

The blocking layer can be a superlattice.

The blocking layer can be doped to allow carrier injection without a significant voltage penalty.

A thickness of the blocking layer can be optimized to prevent carriers from overflowing and reaching the defective layer, without being so thick as to introduce additional defects or impair carrier injection.

The present invention further discloses a nonpolar or semipolar (Al,In,B,Ga)N based optoelectronic device comprising at least an active region, wherein stress relaxation (Misfit Dislocation formation) is at heterointerfaces above and/or below the active region.

The heterointerfaces can comprise lower and upper relaxation heterointerfaces, and the device can further comprise epitaxial layers, between the lower and upper relaxation heterointerfaces, that are fully coherent.

The heterointerfaces can comprise lower and upper heterointerfaces, wherein only the upper heterointerface is relaxed.

The heterointerfaces can comprise lower and upper heterointerfaces, wherein only where only the lower heterointerface is relaxed.

The device can further comprise an (Al,In,B,Ga)N hole blocking layer on the n-side of the device, and/or an (Al,In,B,Ga)N electron blocking layer on the p-side of the device.

The device can be a laser diode.

Stress relaxation below the active region can occur at an interface between an n-cladding layer and an n-waveguiding layer of the laser diode.

Stress relaxation above the active region can occur at an interface between a p-cladding layer and a p-waveguiding of the laser diode.

P-type/n-type waveguiding layers and p-type/n-type cladding layers can comprise different (Al,In,B,Ga)N alloy compositions.

A p-type/n-type waveguiding layer can have a higher refractive index than a p-type/n-type cladding layer.

The device can have few or no Misfit Dislocations (MDs) at the heterointerface between a electron blocking (Al,In,B,Ga)N layer and a p-waveguiding layer of the laser diode.

The device can have few or no MDs at the heterointerface between a hole blocking (Al,In,B,Ga)N layer and an n-waveguiding layer of the laser diode.

### BRIEF DESCRIPTION OF THE DRAWINGS

Referring now to the drawings in which like reference numbers represent corresponding parts throughout:

FIG. 1 is a cross-sectional schematic sample epitaxial structure, showing the HBL in between the relaxed n-InGaN waveguiding (WG) layer, the active region (double quantum well (DQW active), and the electron blocking layer (EBL), wherein the interface containing the Misfit Dislocations (MDs) is also indicated.

FIG. 2 shows fluorescence micrographs of samples having (a) no HBL, (b) a 10 nm thick Al_{0.2}Ga_{0.8}N HBL, and (c) a 20 nm thick Al_{0.2}Ga_{0.8}N HBL, wherein a reduction of dark lines, associated with non-radiative recombination at MDs, occurs for increasing HBL thickness.

FIG. 3 plots electroluminescence (EL) light output power (diamonds), measured through the substrate backside, and voltage (squares) at 20 milliamps (mA) injection current, as a function of HBL thickness in nanometers (nm).

FIG. 4 plots pulsed light-current-voltage (LIV) characteristics of two LDs with relaxed n-InGaN waveguiding layers, one having no HBL and a second having a 10 nm thick Al_{0.2}Ga_{0.8}N HBL.

FIG. 5 is a flowchart illustrating a method of fabricating a (Al,In,B,Ga)N based device comprising a hole blocking layer.

FIG. 6 is a schematic cross-section of a (11-22) laser structure with MD formation at the n-In_{0.09}Ga_{0.91}N/n-GaN and p-GaN/p-In_{0.09}Ga_{0.91}N interface.

FIG. 7 is a schematic of a finished laser device structure with etched facets.

FIG. 8 shows a reciprocal space map of the as-grown (11-22) laser diode (LD) device recorded with the x-ray beam oriented along [11-2-3].

FIG. 9 shows light current voltage(L-I-V) characteristics of a 3 micrometer wide by 1800 micrometer long semipolar (11-22) laser diode, grown on a 100 nm thick stress relaxed n-In_{0.09}Ga_{0.91}N waveguide, wherein the lasing spectrum is shown in the inset.

FIG. 10 is a flowchart illustrating a method of fabricating a nonpolar or semipolar (Al,In,B,Ga)N based optoelectronic device comprising at least an active region, wherein stress relaxation (Misfit Dislocation formation) is at heterointerfaces above and/or below the active region.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Technical Description

Relaxation on semipolar (20-21) (and (11-22)) GaN occurs initially by slip on the c-plane, allowing stress relaxation parallel to the a-direction (m-direction) and a small degree of stress relaxation parallel to the projected c-direction due to the Poission effect. Relaxation occurs through the creation of an array of misfit dislocations (MDs)[2].

Relaxation on nonpolar (10-10) m-plane can also occur on inclined m-planes [4].

Subsequently grown layers coherent to this partially relaxed buffer layer can then be grown with a modified in-plane lattice constant, leading to a change in the lattice mismatch induced strain. For example, growing a high composition InGaN layer on a partially relaxed InGaN buffer layer will lead to reduced strain for the high InGaN layer. Anisotropic strain reduction may lead to fewer non-radiative defects during growth and modified polarization and gain properties.

Device Comprising Hole Blocking Layer

The MDs formed as a result of relaxation are non-radiative recombination centers. Typically they can be buried far away from the active region and have negligible effect on device performance. However, if the MDs are close enough to the active region they can act as a carrier sink and draw carriers out of the active region, leading to greatly reduced internal quantum efficiency. If the relaxed buffer is also used as the lower waveguiding layer of a laser diode (LD), the relaxed interface can only be moved so far from the active region before confinement factor drops off sharply due to excessive broadening of the confined optical mode.

One embodiment of the present invention uses a hole blocking layer (HBL), with significant band offset relative to the quantum barriers (QBs) of the active region, to prevent carrier escape. The hole blocking layer must be n-doped sufficiently such that the HBL doesn't block electron injection into the active region. In this case, the present invention used a nominally Al_{0.2}Ga_{0.8}N layer heavily doped with Si to around 3·10¹⁹ cm⁻³. Without a HBL, electroluminescence (EL) output power in a structure with a partially relaxed lower InGaN waveguide layer is reduced by as much as 50% relative to a reference light-emitting diode (LED). With the HBL, the output power for the device on a relaxed InGaN layer recovered to approximately that of the reference LED.

In addition to carrier confinement, a tensile strained layer grown on a buffer layer, partially relaxed in the compressive sense, may help reduce the excess stress felt in the active region. If the buffer layer isn't fully relaxed, there may be residual stress remaining in the buffer layer, and this stress field may propagate into the active region during growth. Tensile strain in the HBL may act to reduce the excess compressive stress, and prevent defect formation in the active region.

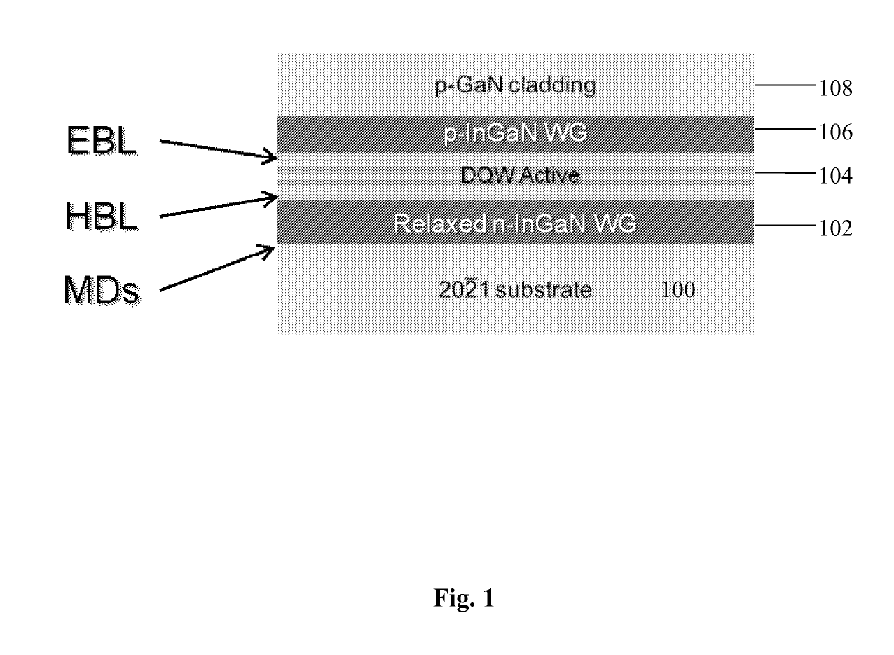

The present invention grew a series of samples using horizontal flow Metal Organic Chemical Vapor Deposition (MOCVD) on (20-21) free standing substrates 100, using the structure illustrated in FIG. 1. The structure comprises a (20-21) substrate 100, a relaxed n-type InGaN waveguiding layer 102 on or above the substrate 100, an HBL on or above the waveguiding layer 102, a double quantum well (DQW) active region 104 on or above the HBL, an electron blocking layer (EBL) on or above the active region 104, a p-type InGaN waveguiding layer 106 on or above the EBL, and a p-type GaN cladding layer 108 on or above the p-type waveguiding layer 106. The composition of the HBL layer was fixed at Al_{0.2}Ga_{0.8}N, and HBL layer thicknesses were 0, 10 and 20 nm. The HBL layers were heavily doped with Si to around 3·10¹⁹ cm⁻³ to facilitate electron injection into the active region.

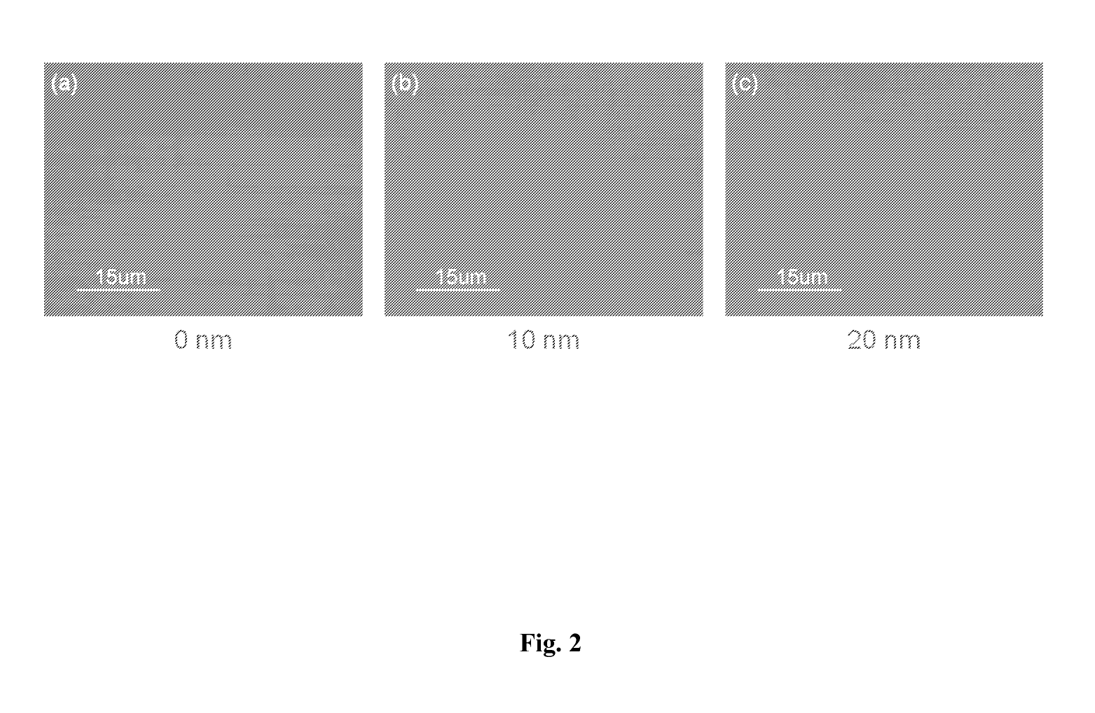

Fluorescence microscopy was used to investigate the impact of the HBL on the defect structure in the active region. FIG. 2 shows fluorescence micrographs of the series of samples that were grown. A significant dark line density is present for the sample without a HBL. These lines are parallel to the a-direction and correspond to the misfit dislocations located at the interface between the partially relaxed 100 nm thick n-In_{0.1}Ga_{0.9}N waveguiding layer and the n-GaN cladding. For the sample with a 10 nm thick HBL, the dark line density is greatly reduced, and for the 20 nm sample the dark line density is virtually eliminated.

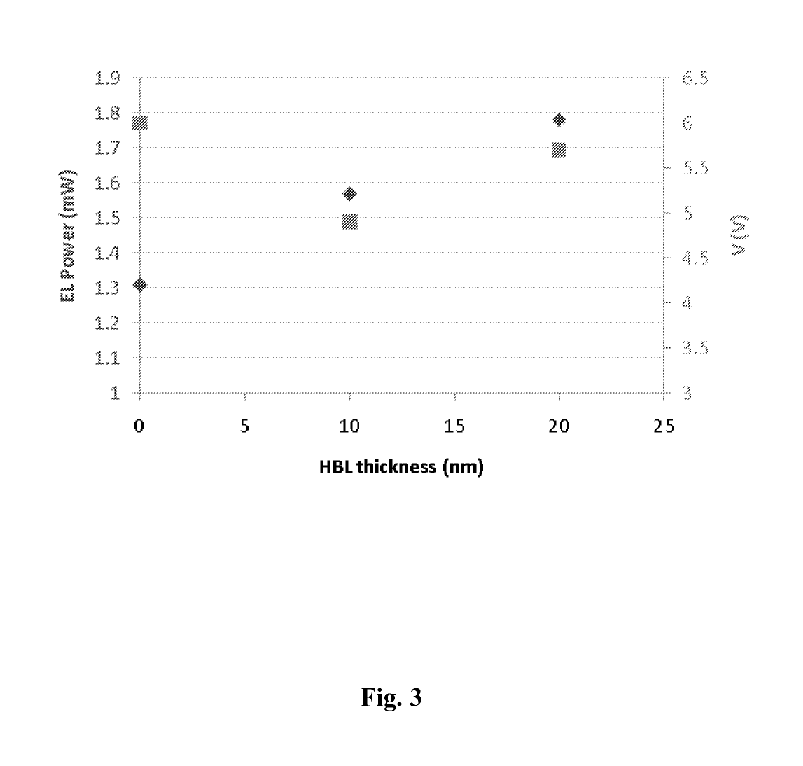

FIG. 3 shows the dependence of output power on HBL thickness. EL intensity increases with increasing HBL thickness and there is no obvious increase in voltage. This data confirms an increase in device performance due to the elimination of non-radiative recombination in the underlying MDs, in agreement with the disappearance of dark MD related lines with HBL thickness illustrated in FIG. 2. The lack of a large voltage penalty suggests the AlGaN band discontinuities can be shifted sufficiently into the valance band to allow electron injection into the active region.

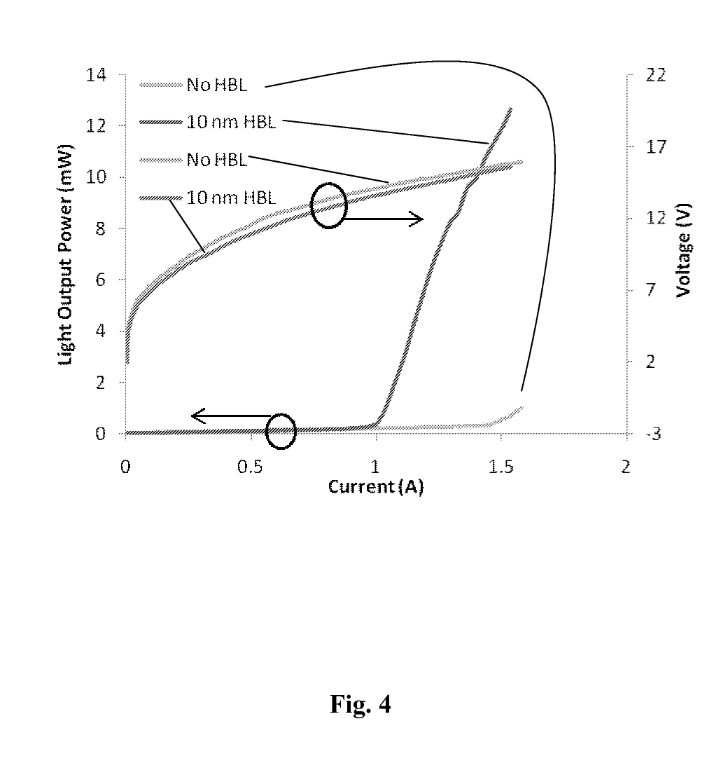

Full LD structures were grown to test the feasibility of an HBL in working devices. The sample structures were similar to FIG. 1, except that they employed an optimized triple quantum well active region. One sample was grown without an HBL, and a second with a 10 nm thick Al_{0.2}Ga_{0.8}N HBL between the partially relaxed n-In_{0.1}Ga_{0.9}N lower waveguiding layer and the active region. FIG. 4 gives LIV curves for both devices, tested under pulsed conditions at 0.015% duty cycle and 150 ns pulses. The threshold current density was high for this demonstration device, around 28 kA/cm² (28 kiloamps per centimeter square), however without the HBL the sample barely reaches threshold, at around two times (2×) the threshold current density. This shows that, despite the perturbation of the optical mode by the introduction of low index material near the active region (the AlGaN HBL), the HBL is essential to prevent holes from escaping to the charged MDs and recombining non-radiatively.

The application of this invention allows for devices grown directly on a relaxed buffer layer without increasing MD mediated non-radiative recombination. It will likely be an essential component in high quality devices grown on relaxed buffer layers, and allows for a greatly expanded design space for devices on relaxed buffers by allowing the relaxed layer relatively close to the active region.

Process Steps

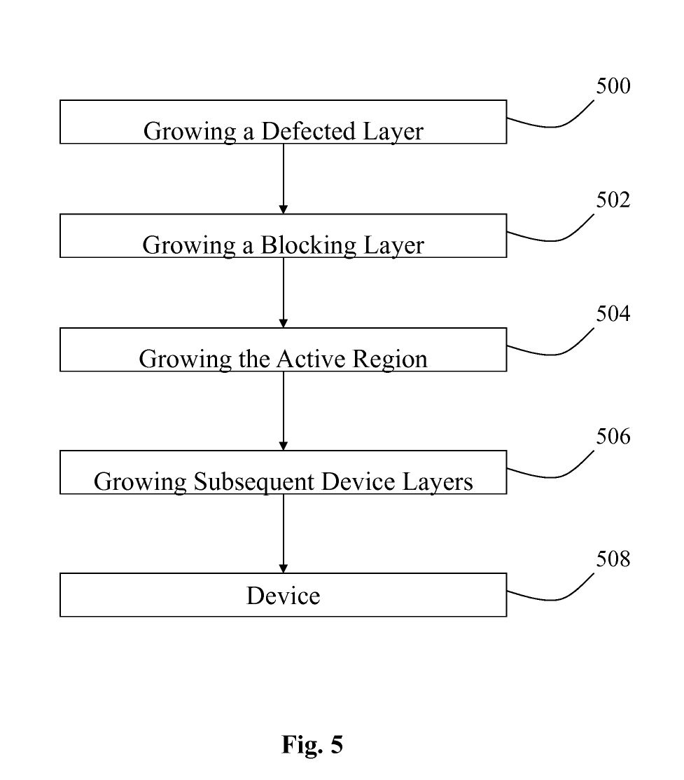

FIG. 5 illustrates a method of fabricating a (Al,In,B,Ga)N based device comprising one or more (Al,In,B,Ga)N layers overlying a semi-polar or non-polar GaN or III-nitride substrate (also referring to FIG. 1). Steps may be added or omitted, as desired.

Block 500 represents growing a defected layer 102 on the substrate 100.

Block 502 represents growing a blocking layer HBL on the defected layer 102.

Block 504 represents growing the active region 104 on the blocking layer HBL.

Block 506 represents growing subsequent device layers 106-108 on the active region 104 if necessary.

Block 508 represents the end result of the method, a device comprising a plurality of (Al,In,B,Ga)N layers overlying a semi-polar or non-polar GaN substrate, wherein the (Al,In,B,Ga)N layers comprise at least a defected layer, a blocking layer, and an active region.

The blocking layer of Block 502 is typically between the active region and a defected layer of the device, and the blocking layer typically comprises a larger band gap than surrounding layers (e.g., the active region) to prevent carriers from escaping the active region to the defected layer. One or more (AlInGaN) device layers can be above and/or below the (Al,In,B,Ga)N layers.

The blocking layer can be a high bandgap layer blocking carriers and the carriers are holes.

The blocking layer can be an AlGaN layer.

The blocking layer can be a superlattice.

The blocking layer can be doped to allow carrier injection without a significant voltage penalty.

A thickness of the blocking layer can be optimized to prevent carriers from overflowing and reaching the defective layer, without being so thick as to introduce additional defects or impair carrier injection.

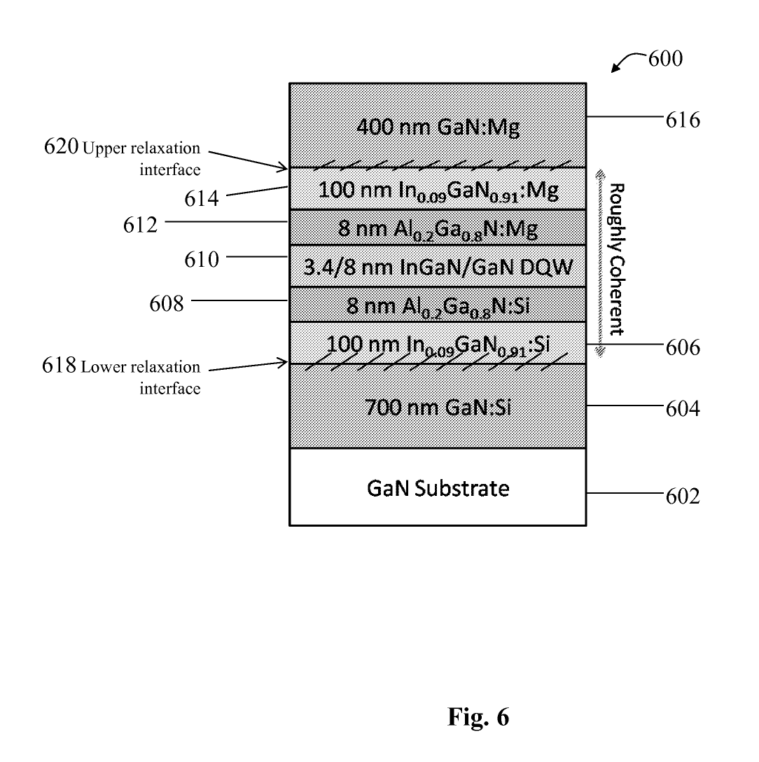

The device can comprise the laser diode structure of FIG. 6 discussed below.

Advantages and Improvements Provided by the Hole Blocking Layer

The present invention has experimentally demonstrated the concept using fluorescence microscopy, photoluminescence, and electroluminescence, and demonstrated its effect on working LDs grown on partially relaxed InGaN waveguiding layers.

The present invention enables an entirely new approach towards achieving high performance devices with highly strained active regions, such as green or ultraviolet (UV) LEDs, LDs, and solar cells, by overcoming negative effects associated with generating MDs. By allowing MDs near the active region, the present invention opens up significant design space for devices.

The present invention can prevent non-radiative recombination, and hole overflow/leakage.

Nonpolar/Semipolar (Al,In,B,Ga)N Lasers with Stress Relaxation

The present invention also describes a nonpolar/semipolar (Al,In,B,Ga)N optoelectronic device with stress relaxation at heterointerfaces above and below the active region. The working prototype is of an (Al,In,B,Ga)N laser device with a waveguide structure that allows stress relaxation (MD formation) to occur at the p-cladding/p-waveguiding and n-waveguiding/n-cladding. In this case, the cladding and waveguiding are (Al,In,B,Ga)N alloys of different compositions, with the cladding layers and waveguiding layers having lower and higher refractive indices, respectively. Depending on distance of the p-cladding/p-waveguiding and n-waveguiding/n-cladding interfaces from the active region, the device may also utilize an Mg(Si)-doped AlₓGa₁₋ₓN electron blocking (hole blocking) layer to prevent carrier recombination at the defective heterointerfaces, as described above.

This embodiment of the present invention describes a laser structure in which Misfit Dislocations (MDs) are allowed to form at the p-cladding/p-waveguiding and n-waveguiding/n-cladding interfaces. Negative effects that the MDs may have on the active region are suppressed by the use of an Mg(Si)-doped (Al,In,B,Ga)N electron blocking (hole blocking) layer. This may allow optimization of the waveguide structure for higher modal confinement without the constraints of MD formation. For example, higher indium composition InGaN waveguiding layers may be used. Also higher aluminum composition and thicker p-AlGaN clads may be used, since the waveguide structure is not limited by the nonpolar/semipolar critical thickness for MD formation.

In some cases, such as semipolar (11-22) lasers, relaxation is almost unavoidable due to the low critical thickness for MD formation. Relaxation at the p-cladding/p-waveguiding and n-waveguiding/n-cladding in this case must occur.

The present invention demonstrates a new method of designing waveguide structures in semipolar and nonpolar (Al,In,B,Ga)N laser diodes. The prototype laser diode device structure 600, as illustrated in FIG. 6, was epitaxially grown on a free standing (11-22) GaN substrate 602 by Metal Organic Chemical Vapor Deposition (MOCVD). The structure comprises a 700 nm thick Si-doped n-GaN cladding layer 604, a stress relaxed 100 nm thick Si-doped n-In_{0.09}Ga_{0.91}N waveguiding layer 606, an 8 nm thick Si-doped n-Al_{0.2}Ga_{0.8}N layer 608, a two period 3.4/10 nm undoped InGaN/GaN active region 610 (3.4 nm thick InGaN layer and 10 nm thick GaN layer), an 8 nm thick Mg-doped p-Al_{0.2}Ga_{0.8}N layer 612, a 100 nm thick Mg-doped p-In_{0.09}Ga_{0.91}N waveguiding layer 614, a 400 nm thick Mg-doped p-GaN cladding layer 616, and a 5 nm thick Mg-doped p+-GaN contact layer.

FIG. 6 also illustrates a lower relaxation interface 618 formed between the GaN layer 602 and the InGaN layer 604. An upper relaxation interface 620 is formed between the InGaN layer 614 and the GaN layer 616.

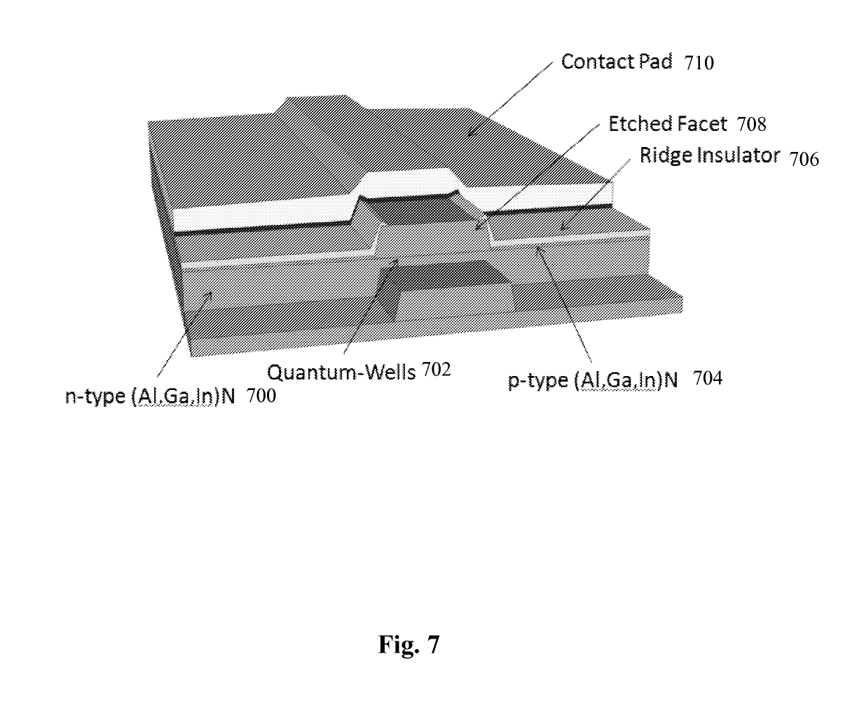

Ridge-waveguide laser structures are then fabricated using conventional photolithography, dry-etching, and lift-off techniques (the schematic of a finished laser structure is shown in FIG. 7). FIG. 7 illustrates a device comprising n-type (Al,Ga,In)N 700, quantum wells 702, p-type (Al,Ga,In)N 704, ridge insulator 706, etched facets 708, and contact pad 710.

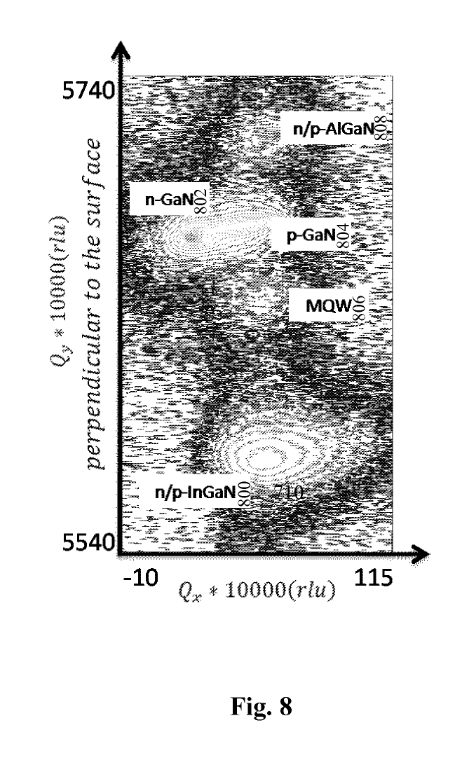

Relaxation at the n-In_{0.09}Ga_{0.91}N/n-GaN and p-GaN/p-In_{0.09}Ga_{0.91}N interface was verified by reciprocal space mapping (RSM) recorded with the x-ray beam oriented parallel to [11-2-3]. The RSM of the laser structure is shown in FIG. 8. The p/n-In_{0.09}Ga_{0.91}N peak 800 is shown to be tilted with respect to the n-GaN substrate 802, suggesting relaxation occurred at the n-In_{0.09}Ga_{0.91}N/n-GaN interface. The p-GaN peak 804 (lower intensity than the n-GaN peak 802) is shown to be tilted back in the opposite sense as the p/n-In_{0.09}Ga_{0.91}N layers, suggesting relaxation to occurred again at the p-GaN/p-In_{0.09}Ga_{0.91}N interface. The multi quantum well (MQW) (peak 806) and the p/n-Al_{0.2}Ga_{0.8}N (peak 808) also appear to be roughly coherent to the n-In_{0.09}Ga_{0.91}N layer.

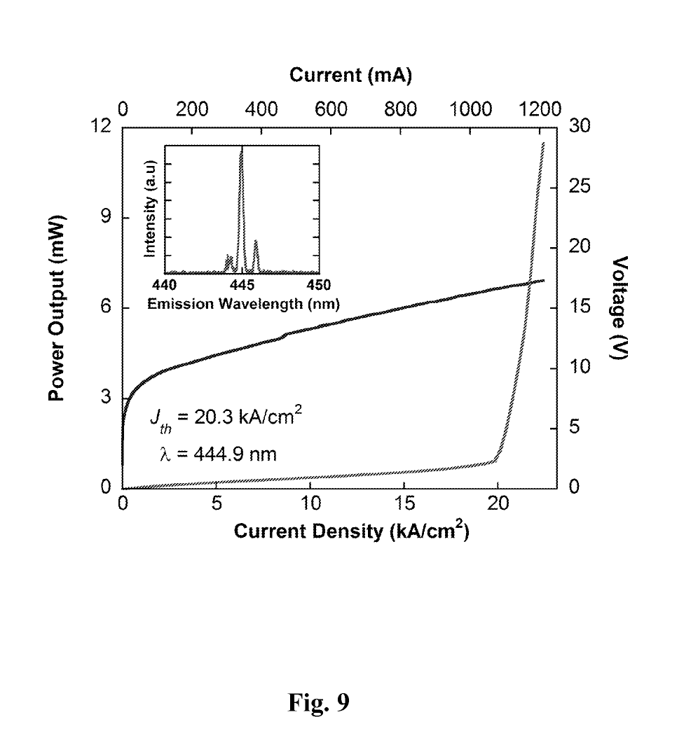

FIG. 9 shows the L-I-V characteristics of a 3 micrometer wide by 1800 micrometer long semipolar (11-22) laser diode, grown on a 100 nm thick stress relaxed n-In_{0.09}Ga_{0.91}N waveguide. The lasing spectrum in the inset shows a clear lasing peak at 444.9 nm. The estimated threshold current was approximately 1090 milliamps (mA), which corresponds to a threshold current density of 20.3 kA/cm² (20.3 kiloamps per centimeter squared).

Process Steps

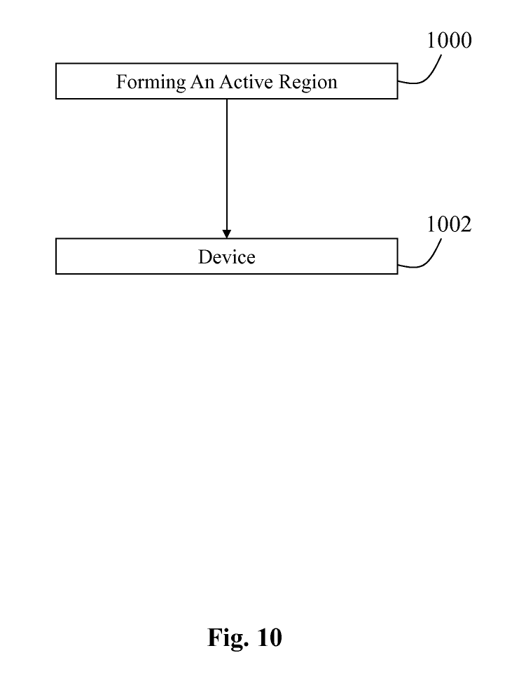

FIG. 10 illustrates a method of fabricating a nonpolar or semipolar (Al,In,B,Ga)N based optoelectronic device. The method can comprise the following steps. Steps can be omitted or added as desired.

Block 1000 represents forming an active region 610, wherein stress relaxation (Misfit Dislocation formation) is at heterointerfaces 618/620 above and/or below the active region 610. The step can comprise growing a GaN layer 604 on a substrate 600, and growing InGaN layer 606 on the GaN layer 604, such that the lower heterointerface 618 is formed between the InGaN 606 and GaN 604. The active region 610 can then be grown on or above the InGaN layer 606. An InGaN layer 614 can be grown on or above the active region 610 and a GaN layer 616 can be grown on or above the InGaN layer 614, such that an upper heterointerface 620 is formed between the InGaN layer 614 and the GaN layer 616.

Additional layers 608, 612, HBL can also be grown between the lower and upper heterointerfaces.

In one example, only the upper heterointerface 620 is relaxed. In another example, only the lower heterointerface 618 is relaxed.

The device's epitaxial layers 606-614, between lower 618 and upper 620 relaxation heterointerfaces, can be fully coherent.

Block 1002 represents the end result of the method, a nonpolar/semipolar (Al,In,B,Ga)N based optoelectronic device with stress relaxation (MD formation) with stress at heterointerfaces 618, 620 above and below the active region 610.

The device can further include a hole blocking and/or electron blocking (Al,In,B,Ga)N layer, as described above.

The (Al,In,B,Ga)N hole blocking layer can be on the n-side of the device. The (Al,In,B,Ga)N electron blocking layer can be on the p-side of the device.

The device can be a laser diode, where the relaxation below the device active region occurs at the n-cladding/n-waveguiding interface.

The device can be a laser diode, where the relaxation above the device active region occurs at the p-cladding/p-waveguiding interface.

The device can be a laser diode, where the p/n-waveguiding and p/n-cladding layers are of different (Al,In,B,Ga)N alloy compositions.

The device can be a laser diode, where the p/n-waveguiding layer has a higher refractive index than the p/n-cladding layer.

The device can be a laser diode having few or no MDs at the heterointerface between the electron blocking (Al,In,B,Ga)N layer and the p-waveguiding layer.

The device can be a laser diode having few or no MDs at the heterointerface between the hole blocking (Al,In,B,Ga)N layer and the n-waveguiding layer.

Advantages and Improvements of Stress Relaxation

The present invention can be used to fabricate Laser diodes, superluminescent diodes, and/or Light Emitting Diodes (LEDs) for display application, lighting, biomedical imaging, illumination, etc.

Existing semipolar/nonpolar (Al,In,B,Ga)N based laser diode devices are typically grown fully coherent without MDs at heterointerface(s). The present invention allows for an entirely new approach towards achieving high performance laser diodes with highly strained active regions, on both semipolar and nonpolar free standing GaN substrates. The present invention's proposed waveguide structure allows for MDs to form at the p-cladding/p-waveguiding and/or n-waveguiding/n-cladding heterointerface(s).This significantly reduces the constraint, placed by critical thickness for MD formation, on waveguide design and can lead to laser structures with improved modal confinement.

Due to the stress relaxation mechanism in semipolar (Al,In,B,Ga)N heteroepitaxial growth, one dimension relaxation will change the in-plane strain state of the active region. In some cases, this can lead to a larger splitting in the valence bands resulting in higher optical gain in the quantum wells (QWs).

Possible Modifications and Variations

The present invention can be used to help realize optoelectronic and electronic devices such as, but not limited to, LEDs, LDs, transistors (e.g., High Electron Mobility Transistors), solar cells, or any other device involving highly strained layers grown on a relaxed buffer layer on semipolar (SP) or nonpolar (NP) GaN. Devices grown incorporating this invention can benefit from the relaxed buffer layer without losing carriers to the associated MDs. The present invention can use high quality relaxed buffer layers to improve on device performance.

Variations include using various possible epitaxial growth techniques (including low pressure MOCVD, atmospheric pressure MOCVD, high pressure MOCVD, Molecular Beam Epitaxy (MBE), etc.)

Different laser device structures can be fabricated.

Different etching and dry-etching techniques can be used, including Inductively Coupled Plasma (ICP)/Rapid Ion Etching (RIE)/Focused ion Beam (FIB)/Chemical Mechanical Polishing (CMP)/Chemically Assisted Ion Beam Etching (CAIBE).

Facet mirrors can be formed by cleaving, for example.

The present invention includes variations in waveguide structures, facets made by two types of etching techniques, or different angles for the facets (e.g., for superluminescent diodes), and/or facet mirrors coated with the same/two different type of dielectrics, etc.

The present invention can obtain improvement of device performance, continuous wave operation for lasers, and increased lasing and spontaneous wavelength. The present invention can optimize the waveguide structure to achieve highest optical confinement.

The present invention can be used to fabricate optoelectronic and electronic devices, such as, but not limited to, Light Emitting Diodes (LEDs), Laser Diodes, solar cells, and transistors (e.g., High Electron Mobility Transistors).

Nomenclature

The terms “(AlInGaN)” “(In,Al)GaN”, or “GaN” as used herein (as well as the terms “III-nitride,” “Group-III nitride”, or “nitride,” used generally) refer to any alloy composition of the (Ga,Al,In,B)N semiconductors having the formula Ga_{w}AlₓIn_{y}B_{z}N where 0≦w≦1, 0≦x≦1, 0≦y≦1, 0≦z≦1, and w+x+y+z=1. These terms are intended to be broadly construed to include respective nitrides of the single species, Ga, Al, In and B, as well as binary, ternary and quaternary compositions of such Group III metal species. Accordingly, it will be appreciated that the discussion of the invention hereinafter in reference to GaN and InGaN materials is applicable to the formation of various other (Ga,Al,In,B)N material species. Further, (Ga,Al,In,B)N materials within the scope of the invention may further include minor quantities of dopants and/or other impurity or inclusional materials.

Many (Ga,Al,In,B)N devices are grown along the polar c-plane of the crystal, although this results in an undesirable quantum-confined Stark effect (QCSE), due to the existence of strong piezoelectric and spontaneous polarizations. One approach to decreasing polarization effects in (Ga,Al,In,B)N devices is to grow the devices on nonpolar or semipolar planes of the crystal.

The term “nonpolar plane” includes the {11-20} planes, known collectively as a-planes, and the {10-10} planes, known collectively as m-planes. Such planes contain equal numbers of Group-III (e.g., gallium) and nitrogen atoms per plane and are charge-neutral. Subsequent nonpolar layers are equivalent to one another, so the bulk crystal will not be polarized along the growth direction.

The term “semipolar plane” can be used to refer to any plane that cannot be classified as c-plane, a-plane, or m-plane. In crystallographic terms, a semipolar plane would be any plane that has at least two nonzero h, i, or k Miller indices and a nonzero 1 Miller index. Subsequent semipolar layers are equivalent to one another, so the crystal will have reduced polarization along the growth direction.

For a layer X grown on a layer Y, for the case of coherent growth, the in-plane lattice constant(s) of X are constrained to be the same as the underlying layer Y. If X is fully relaxed, then the lattice constants of X assume their natural (i.e. in the absence of any strain) value. If X is neither coherent nor fully relaxed with respect to Y, then it is considered to be partially relaxed. In some cases, the substrate might have some residual strain.

The equilibrium critical thickness corresponds to the case when it is energetically favorable to form one misfit dislocation at the layer/substrate interface.

Experimental, or kinetic critical thickness, is always somewhat or significantly larger than the equilibrium critical thickness. However, regardless of whether the critical thickness is the equilibrium or kinetic critical thickness, the critical thickness corresponds to the thickness where a layer transforms from fully coherent to partially relaxed.

Another example of critical thickness is the Matthews Blakeslee critical thickness.

Throughout the disclosure, layers that are on an underlying layer can be on, above, or overlying the underlying layer, for example.

### REFERENCES

The following references are incorporated by reference herein.

[1] A. Tyagi, F. Wu, E. C. Young, A. Chakraborty, H. Ohta, R. Bhat, K. Fujito, S. P. DenBaars, S. Nakamura and J. S. Speck, Appl. Phys. Lett. 95, p. 251905 (2009).

[2] E. C. Young, C. S. Gallinat, A. E. Romanov, A. Tyagi, F. Wu and J. S. Speck, Appl. Phys. Express 3 p. 111002 (2010).

[3] S. Yoshida, T. Yokogawa, Y. Imai, S. Kimura, and O. Sakata, Appl. Phys. Lett. 99, p. 131909 (2011).

[4] U.S. Patent Publication No. 2010/0008393, by Enya et. al.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A III-nitride based device comprising:
a plurality of III-nitride layers overlying a semi-polar or non-polar GaN substrate, wherein:
the III-nitride layers comprise at least a defected layer, a blocking layer, and an active region,
the blocking layer is between the active region and the defected layer of the device, and
the blocking layer comprises a larger band gap than surrounding layers to prevent carriers from escaping the active region to the defected layer; and
one or more III-nitride device layers above, below, or above and below the III-nitride layers.

2. The device of claim 1, wherein the blocking layer is a high bandgap layer blocking one or more carriers and the carriers are holes.

3. The device of claim 1, wherein the blocking layer is an AlGaN layer.

4. The device of claim 1, wherein the blocking layer is a superlattice.

5. The device of claim 1, wherein the blocking layer is doped to allow carrier injection without a significant voltage penalty.

6. The device of claim 1, wherein a thickness of the blocking layer is optimized to prevent carriers from overflowing and reaching the defective layer, without being so thick as to introduce additional defects or impair carrier injection.

7. A nonpolar or semipolar III-nitride based optoelectronic device comprising at least:
an active region, wherein stress relaxation or misfit dislocation formation is at heterointerfaces above, below, or above and below the active region.

8. The device of claim 7, wherein:
the heterointerfaces comprise lower and upper relaxation heterointerfaces,
the device further comprises epitaxial layers, between the lower and upper relaxation heterointerfaces, that are fully coherent.

9. The device of claim 7, wherein:
the heterointerfaces comprise lower and upper heterointerfaces, and
only the upper heterointerface is relaxed.

10. The device of claim 7, wherein:
the heterointerfaces comprise lower and upper heterointerfaces, and
only the lower heterointerface is relaxed.

11. The device of claim 7, further comprising a III-nitride hole blocking layer on the n-side of the device, or an III-nitride electron blocking layer on the p-side of the device, or both the hole blocking layer and the electron blocking layer.

12. The device of claim 7, wherein the device is a laser diode.

13. The device of claim 12, wherein the stress relaxation below the active region occurs at an interface between an n-cladding layer and an n-waveguiding layer of the laser diode.

14. The device of claim 12, wherein the stress relaxation above the active region occurs at an interface between a p-cladding layer and a p-waveguiding of the laser diode.

15. The device of claim 12, wherein p-type/n-type waveguiding layers and p-type/n-type cladding layers comprise different III-nitride alloy compositions.

16. The device of claim 12, wherein a p-type/n-type waveguiding layer has a higher refractive index than a p-type/n-type cladding layer.

17. The device of claim 12, having few or no Misfit Dislocations (MDs) at the heterointerface between a electron blocking III-nitride layer and a p-waveguiding layer of the laser diode.

18. The device of claim 12, having few or no MDs at the heterointerface between a hole blocking III-nitride layer and an n-waveguiding layer of the laser diode.
